(19) United States
(12) Patent Application Publication
(10) Pub. No.: US 2019/0341288 A1
(43) Pub. Date: Nov. 7, 2019

(54) LOWER ELECTRODE WAFER CHUCK OF AN ETCHING MACHINE

(71) Applicant: JIANGSU LEUVEN INSTRUMMENTS CO. LTD, Jiangsu (CN)

(72) Inventors: Dongchen CHE, Jiangsu (CN); Na LI, Jiangsu (CN); Dongdong HU, Jiangsu (CN); Kaidong XU, Jiangsu (CN)

(21) Appl. No.: 16/515,199

(22) Filed: Jul. 18, 2019

Related U.S. Application Data
(63) Continuation of application No. PCT/CN2017/108108, filed on Oct. 27, 2017.

(30) Foreign Application Priority Data
Jan. 19, 2017 (CN) 201720064444.0

(51) Int. Cl. H01L 21/687; H01L 21/67; H01J 37/20

(52) U.S. Cl. CPC H01L 21/687; H01J 37/20; H01L 21/67069

(57) ABSTRACT

A lower electrode wafer chuck of an etching machine comprises an upper stage, configured for placing a wafer, coupled to a lower stage. The upper stage includes a lower surface that includes a cooling liquid circulation groove, and an upper surface that includes a cooling gas distribution groove and a cooling gas outlet hole. The lower stage includes a cooling liquid inlet, a cooling liquid outlet and a cooling gas inlet hole, the cooling liquid inlet and the cooling liquid outlet both being communicated with the cooling liquid circulation groove. To cool a lower electrode, cooling liquid enters the cooling liquid circulation groove from the cooling liquid inlet, and then flows out the cooling liquid outlet. To cool a wafer on the upper stage, cooling gas enters from the cooling gas inlet hole, passes through the cooling gas outlet hole, and diffuses into the cooling gas distribution groove.

### CROSS REFERENCE TO RELATED APPLICATIONS

This is a Continuation application of International Application Serial No. PCT/CN2017/108108, filed on Oct. 27, 2017, which claims the benefit of Chinese Application No. 201720064444.0, filed on Jan. 19, 2017, the disclosures of which are hereby incorporated by reference.

### BACKGROUND

The present disclosure relates to the field of semiconductor technology, and in particular to a lower electrode wafer chuck of an etching machine.

A lower electrode wafer chuck used in a plasma etching process is a structure for fixing a wafer to be etched, and a suitable fixing structure is important for the reliability, stability and repeatability of the plasma etching process. When selecting a wafer fixing structure, it is necessary to consider a size of a wafer to be etched, a gas and flow distribution thereof in an etching process, the physical and chemical effects of the material used in the fixing structure on the etching process, and the thermal effects of the etching process and other factors. For a structure in a process with RF or DC bias, an effect of the electrodes on the electromagnetic field distribution of the wafer chuck should also be considered when a fixing structure is selected.

In order to realize a plasma etching process, the lower electrode is required to have an adsorption capacity to the wafer and a cooling function against the heat generated by the etching process. In the prior art, a wafer chuck usually adopts aluminum alloy anodic oxidation, and has a helium gas cooling and water cooling structure. This type of wafer chuck has a complicated structure and is difficult for installation and maintenance. Moreover, when a temperature of the cooling water is low, condensed water droplets or reactive polymers are prone to occur on the exterior of the wafer chuck or around the lower electrode, resulting in a decrease in the etching rate, thereby affecting the uniformity and stability of the etching process.

### BRIEF SUMMARY

The present disclosure is directed to providing a lower electrode wafer chuck for an etching machine to improve the stability, uniformity, and repeatability of a plasma etching process.

The lower electrode wafer chuck of the etching machine of the present disclosure comprises an upper stage and a lower stage connected to each other, wherein the upper stage is configured for placing a wafer, and a lower surface of the upper stage is provided with a cooling liquid circulation groove, and an upper surface of the upper stage is provided with a cooling gas distribution groove and a cooling gas outlet hole, and the lower stage is provided with a through hole at a center thereof for matching and mounting with a centre mechanism of the etching machine, and has a cooling liquid inlet, a cooling liquid outlet and a cooling gas inlet hole, the cooling liquid inlet and the cooling liquid outlet both being communicated with the cooling liquid circulation groove; wherein when a lower electrode is cooled, a cooling liquid enters the cooling liquid circulation groove of the upper stage from the cooling liquid inlet of the lower stage, and then flows out from the cooling liquid outlet of the lower stage; and when a wafer on the surface of the upper stage is cooled, a cooling gas enters from a cooling gas inlet hole of the lower stage, passes through the cooling gas outlet hole of the upper stage, and diffuses into the cooling gas distribution groove.

In the lower electrode wafer chuck of the etching machine of the present disclosure, preferably, the cooling gas distribution groove includes a plurality of concentric annular grooves communicated with one another through radial grooves.

In the lower electrode wafer chuck of the etching machine of the present disclosure, it is preferable that the cooling gas outlet holes are annularly distributed.

In the lower electrode wafer chuck of the etching machine of the present disclosure, preferably, the cooling gas outlet holes are located on an innermost annular groove in the cooling gas distribution grooves.

In the lower electrode wafer chuck of the etching machine of the present disclosure, it is preferable that the cooling gas outlet holes are uniformly distributed.

In the lower electrode wafer chuck of the etching machine of the present disclosure, it is preferable that a wafer anti-slip zone is provided at an edge region of the upper surface of the upper stage.

In the lower electrode wafer chuck of the etching machine of the present disclosure, preferably, the wafer anti-slip zone includes a depressed annular step and an adhesive film, and the depressed annular step is located at an edge of the upper surface of the upper stage. The adhesive film is disposed on the annular step, and a thickness of the adhesive film is the same as the height of the depressed annular step.

In the lower electrode wafer chuck of the etching machine of the present disclosure, it is preferable that the depressed annular step has a width of 5˜10 mm and a height of 0.1˜0.3 mm.

In the lower electrode wafer chuck of the etching machine of the present disclosure, it is preferable that the adhesive film is a polyimide film.

In the lower electrode wafer chuck of the etching machine of the present disclosure, preferably, the upper stage and the lower stage are fastened by bolts.

The lower electrode wafer chuck of the etching machine of the invention has good wafer adsorption capacity and has a significant cooling function for the heat generated during the etching process. It is simple in structure, easy for implementation, low in cost and remarkable in effect.

### BRIEF DESCRIPTION OF THE SEVERAL VIEWS OF THE DRAWINGS

In order to more clearly illustrate the specific embodiments of the present disclosure or the technical solutions in the prior art, the drawings to be used in the description of the specific embodiments of the invention or the prior art will be briefly described below. Apparently, the drawings described in the following description just show some embodiments of the present invention, and those skilled in the art can obtain other drawings based on these drawings without any creative work.

FIG. 1 is a schematic perspective view showing a lower electrode wafer chuck of an etching machine.

FIG. 2 is a bottom view of an upper stage of the lower electrode wafer chuck of the etching machine.

FIG. 3 is a plan view of the upper stage of the lower electrode wafer chuck of the etching machine.

FIG. 4 is a schematic perspective view showing a lower stage of the lower electrode wafer chuck of the etching machine.

FIG. 5 is a plan view showing another embodiment of an upper stage of a lower electrode wafer chuck of an etching machine.

In the drawings:
1˜upper stage; 2˜lower stage; 11˜cooling liquid circulation groove;
12˜cooling gas distribution groove; 13˜cooling gas outlet hole;
14˜wafer anti-slip zone; 21˜through hole; 22˜cooling liquid inlet;
23˜cooling liquid outlet; 24˜cooling gas inlet hole.

### DETAILED DESCRIPTION

In order to make clearer the objects, the solutions and the advantages of the present invention, the technical solutions in the embodiments of the present invention will be clearly and completely described in the following with reference to the accompanying drawings in the embodiments of the present invention. It should be appreciated that the specific examples described herein are only for illustrating the invention rather than limiting the invention. The described embodiments are only some of the embodiments of the invention rather than all of the embodiments. All other embodiments obtained by a person of ordinary skill in the art based on the embodiments of the present disclosure without creative efforts are within the scope of the present disclosure.

In the description of the present disclosure, it is to be appreciated that the orientations or positional relationships indicated by the terms “upper”, “lower”, “center”, “edge” and the like are based on the drawings, only for the purpose of facilitating and simplifying the description of the invention, rather than indicating or implying that the devices or elements indicated thereby must have certain orientations, or be constituted or operate in a certain orientation. Therefore, these terms are not intended to limit the invention.

In the description of the present disclosure, it should be noted that the terms “attach”, “connect”, and “couple” and the like are to be understood broadly, unless otherwise explicitly defined and regulated. For example, they may be fixed connection, detachable connection, or integral connection; mechanical connection or electrical connection; direct connection or indirectly connected through an intermediate medium or internal communication of two components. A person skilled in the art shall understand the specific meaning of the above terms in the present disclosure according to actual situations.

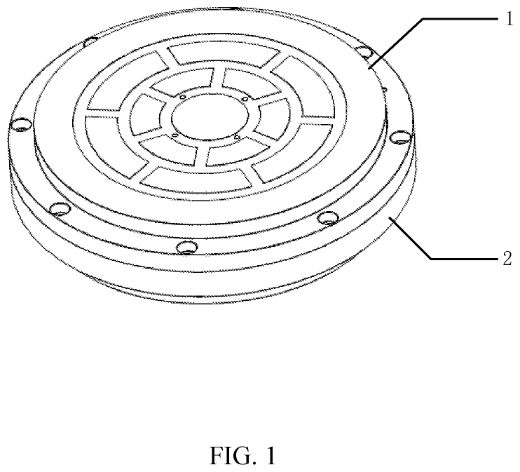

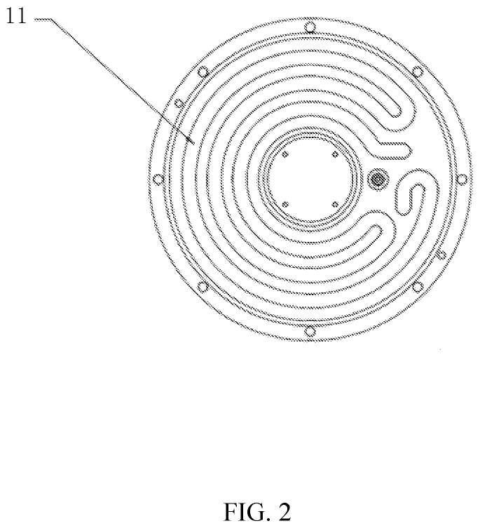

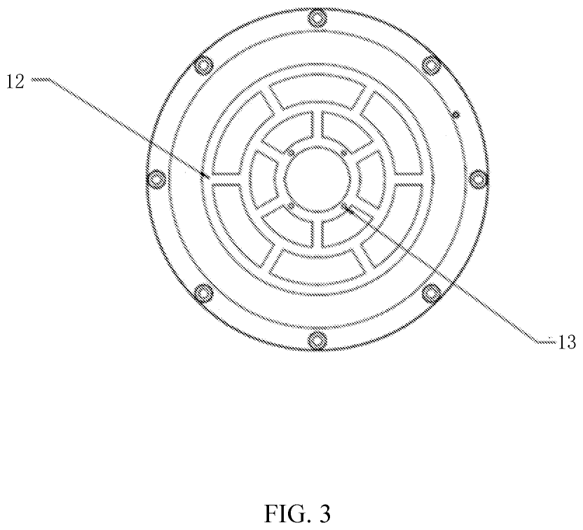

FIG. 1 is a schematic perspective view showing a lower electrode wafer chuck of an etching machine according to an embodiment of the invention. As shown in FIG. 1, the lower electrode wafer chuck of the etching machine of the present embodiment comprises an upper stage 1 and a lower stage 2, and the upper stage 1 and the lower stage 2 are fastened by bolts. The upper stage 1 is used to place a wafer. A cooling liquid circulation groove 11 is provided on a lower surface of the upper stage 1. FIG. 2 is a bottom view of the upper stage of the lower electrode wafer chuck of the etching machine. As shown in FIG. 2, the cooling liquid circulation groove 11 is almost spread over the whole lower surface of the upper stage, thereby increasing the cooling area and improving the cooling effect. FIG. 3 is a plan view of the upper stage of the lower electrode wafer chuck of the etching machine. As shown in FIG. 3, the upper surface of the upper stage 1 is provided with a cooling gas distribution groove 12 and cooling a gas outlet hole 13. Preferably, the cooling gas distribution groove 12 includes a plurality of concentric annular grooves communicated each other through radial grooves. The cooling gas outlet holes 13 are evenly distributed and have a ring shape. In a specific example of the invention illustrated in FIG. 3, there are three groups of cooling gas distribution grooves 12, each group consisting of one annular groove and six radial grooves. The cooling gas outlet holes 13 are located on the innermost annular groove of the cooling gas distribution groove 12. However, the present invention is not limited thereto, and the number and shape of the cooling gas distribution grooves, the number and shape of the cooling gas outlet holes, and the like can be adaptively adjusted according to actual needs. Further, the cooling gas outlet holes may not be located on the annular groove but may be in communication with the annular grooves through the radial grooves or the like, as long as the cooling gas can be diffused to the upper surface of the upper stage through the cooling gas outlet hole(s) and the cooling gas distribution groove(s) to cool the wafer placed on the upper surface of the upper stage.

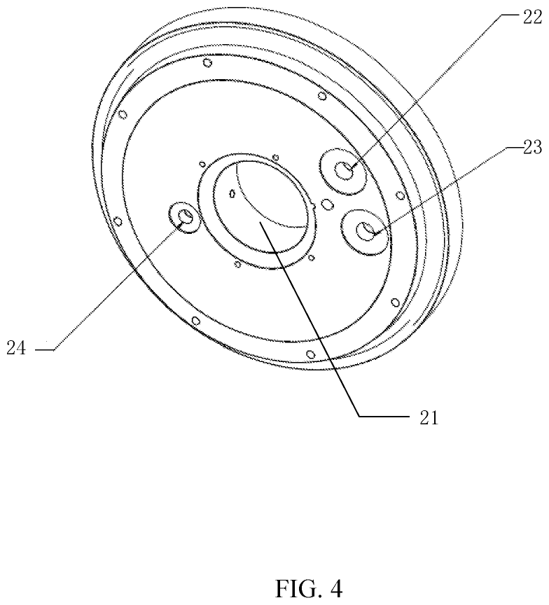

FIG. 4 is a schematic perspective view showing the lower stage of the lower electrode wafer chuck of the etching machine. As shown in FIG. 4, a center of the lower stage 2 is provided with a through hole 21 for matching and mounting with a centre mechanism of the etching machine. The lower stage 2 has a cooling liquid inlet 22, a cooling liquid outlet 23, and a cooling gas inlet hole 24, and both the cooling liquid inlet 22 and the cooling liquid outlet 23 communicate with the cooling liquid circulation groove 11. When the lower electrode is cooled, the cooling liquid enters into the cooling liquid circulation groove 11 of the upper stage 1 from the cooling liquid inlet 22 of the lower stage 2, and then flows out from the cooling liquid outlet 23 of the lower stage 2. When a wafer on the upper surface of the upper stage 1 is cooled, the cooling gas enters from the cooling gas inlet hole 24 of the lower stage 2, passes through the cooling gas outlet holes 13 of the upper stage 1, and diffuses into the cooling gas distribution groove 12.

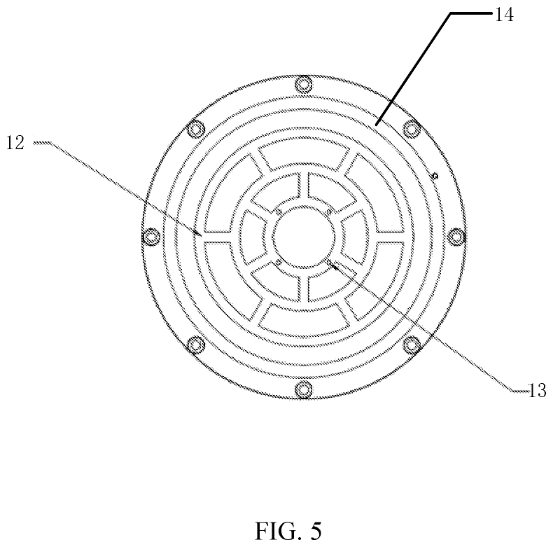

In order to effectively reduce sliding of the wafer on the surface of the upper stage and improve stability, in another embodiment of the present disclosure, a wafer anti-slip zone 14 is disposed at an edge region of the upper surface of the upper stage 1, as shown in FIG. 5. The wafer anti-slip zone can be formed, for example, by removing a ring of material at the edge of the upper surface of the upper stage 1 to form a depressed annular step, and then forming an adhesive film such as a polyimide film or the like on the surface of the annular step. Preferably, a thickness of the adhesive film is equal to a thickness of the removed material, that is, a height of the depressed annular step, so that the upper surface of the upper stage 1 is still flat. A width of the depressed annular step is preferably 5˜10 mm, and the height is preferably 0.1˜0.3 mm. Of course, the present invention is not limited thereto. For example, a plurality of wafer anti-slip zones 14 may be provided, that is, a plurality of circles of annular materials are removed from the upper surface of the upper stage 1 to form a plurality of depressed annular steps, and then an adhesive film such as a polyimide film or the like is formed on the surfaces of the annular steps. Further, the way to form the wafer anti-slip zone is not limited thereto, and may be other suitable ways.

The lower electrode wafer chuck of the etching machine of the invention has good wafer adsorption capacity and a significant cooling effect for the heat generated during the etching process. It is simple in structure, easy for implementation, low in cost and remarkable in effect. Its application to the etching machine can further improve the stability, uniformity and repeatability of the plasma etching process.

The above are only specific embodiments of the present invention, but the scope of the present invention is not limited thereto. Any changes or substitutions easily considered by a person skilled in the art within the technical scope of the present disclosure also fall within the scope of the present invention.

What is claimed is:

1. A lower electrode wafer chuck of an etching machine, comprising:
an upper stage and a lower stage, which are connected to each other, wherein the upper stage is configured for placing a wafer, and a lower surface of the upper stage is provided with a cooling liquid circulation groove, and an upper surface of the upper stage is provided with a cooling gas distribution groove and a cooling gas outlet hole,
the lower stage is provided with a through hole at a center thereof for matching and mounting with a centre mechanism of the etching machine, and has a cooling liquid inlet, a cooling liquid outlet and a cooling gas inlet hole, the cooling liquid inlet and the cooling liquid outlet both being communicated with the cooling liquid circulation groove;
wherein when a lower electrode is cooled, a cooling liquid enters the cooling liquid circulation groove of the upper stage from the cooling liquid inlet of the lower stage, and then flows out from the cooling liquid outlet of the lower stage; and
when a wafer on the surface of the upper stage is cooled, a cooling gas enters from a cooling gas inlet hole of the lower stage, passes through the cooling gas outlet hole of the upper stage, and diffuses into the cooling gas distribution groove.

2. The lower electrode wafer chuck of the etching machine according to claim 1, wherein
the cooling gas distribution groove includes a plurality of concentric annular grooves communicated with one another through radial grooves.

3. The lower electrode wafer chuck of the etching machine according to claim 1, wherein
there is a plurality of annularly distributed cooling gas outlet holes.

4. The lower electrode wafer chuck of the etching machine according to claim 3, wherein
the cooling gas outlet holes are located on an innermost annular groove in the cooling gas distribution grooves.

5. The lower electrode wafer chuck of the etching machine according to claim 3, wherein
the cooling gas outlet holes are uniformly distributed.

6. The lower electrode wafer chuck of the etching machine according to claim 1, wherein
a wafer anti-slip zone is provided at an edge region of the upper surface of the upper stage.

7. The lower electrode wafer chuck of the etching machine according to claim 6, wherein
the wafer anti-slip zone includes a depressed annular step and an adhesive film, and the depressed annular step is located at an edge of the upper surface of the upper stage; the adhesive film is disposed on the annular step, and a thickness of the adhesive film is the same as the height of the depressed annular step.

8. The lower electrode wafer chuck of the etching machine according to claim 7, wherein
the depressed annular step has a width of 5˜10 mm and a height of 0.1˜0.3 mm.

9. The lower electrode wafer chuck of the etching machine according to claim 7, wherein
the adhesive film is a polyimide film.

10. The lower electrode wafer chuck of the etching machine according to claim 1, wherein
the upper stage and the lower stage are fastened by bolts.
